(19) United States
(12) Patent Application Publication
(10) Pub. No.: US 2025/0337390 A1
(43) Pub. Date: Oct. 30, 2025

(54) Elastic Wave Device

(71) Applicant: Sanan Japan Technology Corporation, Tokyo (JP)

(72) Inventors: Fumiaki ISAKA, Tokyo (JP); Shinichi SHIOI, Tokyo (JP)

(21) Appl. No.: 19/172,877

(22) Filed: Apr. 8, 2025

(30) Foreign Application Priority Data
Apr. 25, 2024 (JP) 2024-071989

(51) Int. Cl. H03H 9/25; H03H 9/02; H03H 9/145

(52) U.S. Cl. CPC H03H 9/25; H03H 9/02818; H03H 9/14541

(57) ABSTRACT

An elastic wave device comprises a piezoelectric layer and an IDT electrode formed on the piezoelectric layer, wherein the IDT electrode includes a first bus bar and a second bus bar opposed to the first bus bar; in a top view, the first bus bar and the second bus bar each have multiple stepped portions on their facing sides, with these stepped portions aligned parallel to a propagation direction of the surface acoustic wave, and a distance between the corresponding stepped portions of the first bus bar and the second bus bar is uniform; wherein adjacent of the stepped portions are arranged at different positions in a direction from the first bus bar to the second bus bar, a step portion is provided between them.

### CROSS-REFERENCE TO RELATED APPLICATION

The present disclosure claims priority to Japanese Patent Application No. 2024-71989 filed Apr. 25, 2024, the contents of which are herein incorporated by reference in its entirety.

### FIELD

This application relates to the field of mobile communication devices and, more particularly, to an elastic wave device.

### BACKGROUND

As an elastic wave resonator utilizing surface acoustic waves, a surface acoustic wave (SAW) resonator is known, which includes an interdigital transducer (IDT) electrode provided on the main surface of a piezoelectric substrate. Such a SAW resonator can be used, for example, in transmission filters and reception filters of duplexers. In this type of elastic wave resonator, transverse modes are generated. Transverse modes cause undesirable effects such as spurious responses and losses in the passband and should therefore be suppressed.

Patent Document 1 (Japanese Unexamined Patent Application Publication No. 2020-92422) discloses an IDT electrode having curved sections arranged in a specific configuration, which imparts curvature to the waveguide of the elastic wave resonator, thereby suppressing transverse modes in the elastic wave resonator.

Patent Document 2 (Japanese Unexamined Patent Application Publication No. 2000-286663) discloses a surface acoustic wave (SAW) resonator in which transverse modes reflected at one bus bar are canceled out by transverse modes reflected at the other bus bar, thereby effectively suppressing transverse modes.

As described above, further improvements are required in elastic wave devices using such IDT electrodes by suppressing the transverse mode.

### SUMMARY

Some examples described herein may address the above-described problems. Some examples described herein may have an object to provide an acoustic wave device capable of suppressing transverse-mode spurious.

In some examples, an acoustic wave device comprises a piezoelectric layer and an interdigital transducer (IDT) electrode formed on the piezoelectric layer, and the IDT electrode includes a first bus bar and a second bus bar opposed to the first bus bar.

In a top view, the first bus bar and the second bus bar each have multiple stepped portions on the facing sides, with these stepped portions aligned parallel to the propagation direction of the surface acoustic wave, wherein adjacent stepped portions are arranged at different positions in a direction from the first bus bar to the second bus bar; and a step portion is provided between adjacent stepped portions; wherein the stepped portions of the first bus bar and the corresponding stepped portions of the second bus bar are equidistant from each other in the top view.

According to the acoustic wave device, by providing adjacent stepped portions on the first bus bar and the second bus bar of the IDT electrode, and arranging these stepped portions at different positions in the direction from the first bus bar to the second bus bar, it is possible to achieve an elastic wave resonator capable of suppressing transverse modes.

The details of one or more embodiments of the present application are set forth in the accompanying drawings and the description below. Other features, objects, and advantages of the present application will be apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a cross-sectional view of the elastic wave device according to a first embodiment.

FIG. 2 is a top view illustrating an IDT electrode of the elastic wave device according to the first embodiment.

FIG. 3a is a graph showing the relationship between the real part of admittance and frequency for the elastic wave device in Example 1.

FIG. 3b is a graph showing the relationship between the real part of admittance and frequency for the elastic wave device in Example 2.

FIG. 3c is a graph showing the relationship between the real part of admittance and frequency for the comparative example of the elastic wave device.

FIG. 4 is a graph simultaneously showing the relationship between the real part of admittance and frequency for the elastic wave devices in Example 1, Example 2, and the comparative example.

FIG. 5 is a top view illustrating the IDT electrode of a comparative example of the elastic wave device.

FIG. 6 is a graph simultaneously showing the relationship between the real part of admittance and frequency for the elastic wave device in Example 3 and the comparative example.

FIG. 7 is a top view illustrating the IDT electrode of the elastic wave device according to a second embodiment.

FIG. 8a is a graph showing the relationship between the real part of admittance and frequency for the elastic wave device in Example 4.

FIG. 8b is a graph showing the relationship between the real part of admittance and frequency for the elastic wave device in Example 5.

FIG. 8c is a graph showing the relationship between the real part of admittance and frequency for the comparative example of the elastic wave device.

FIG. 9 is a graph simultaneously showing the relationship between the real part of admittance and frequency for the elastic wave devices in Example 4, Example 5, and the comparative example.

FIG. 10 is a top view illustrating the IDT electrode of the elastic wave device according to a third embodiment.

FIG. 11 is a top view illustrating the IDT electrode of the elastic wave device according to a fourth embodiment.

FIG. 12 is a top view illustrating the IDT electrode of the elastic wave device according to a fifth embodiment.

FIG. 13 is a partially enlarged view illustrating an IDT electrode of the fifth embodiment.

FIG. 14 is a top view illustrating an IDT electrode of the elastic wave device according to a sixth embodiment.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### First Embodiment

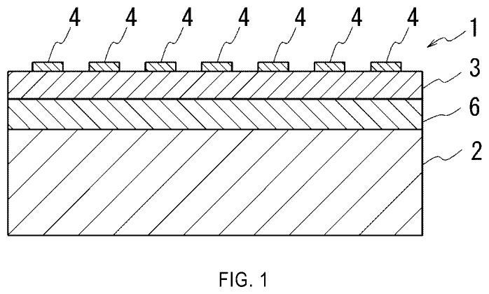

FIG. 1 is a cross-sectional view illustrating the first embodiment of the elastic wave device. The elastic wave device 1 is a SAW resonator that includes a support substrate 2, a piezoelectric layer 3, an IDT electrode 4 formed on the piezoelectric layer 3, and an intermediate layer 6 disposed between the support substrate 2 and the piezoelectric layer 3.

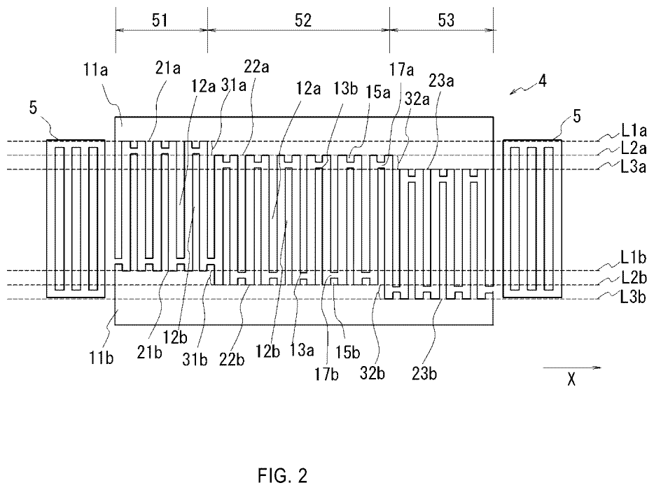

FIG. 2 is a top view illustrating the IDT electrode 4 and the reflector 5 provided on the main surface of the piezoelectric layer 3 in the elastic wave device 1. As shown in FIG. 2, the IDT electrode 4 includes a first bus bar 11a, a second bus bar 11b, multiple electrode fingers 12a extending from the first bus bar 11a toward the second bus bar 11b, multiple electrode fingers 12b extending from the second bus bar 11b toward the first bus bar 11a, and dummy electrodes 15a and 15b respectively facing the electrode fingers 12a and 12b.

Gaps 17b and 17a are respectively formed between the end portions 13a and 13b of the electrode fingers 12a and 12b and the dummy electrodes 15b and 15a.

The first bus bar 11a and the second bus bar 11b are respectively connected to an input terminal (not shown) and an output terminal (not shown). When a high-frequency signal is input to the input and output terminals, an electric field is generated between the electrodes, thereby exciting surface acoustic waves, which propagate on the piezoelectric layer 3 and are reflected at the reflector 5, generating electrical resonance. The resonance frequency fR is determined by the following relationship: when the wavelength of the surface acoustic wave propagating on the piezoelectric layer 3 is λ and the electrode pitch is P, the condition P=λ/2 is satisfied.

As the material of the support substrate 2, crystalline silicon or crystalline sapphire may be used. However, the material of the support substrate 2 is not limited to these and may include other materials such as polycrystalline silicon, polycrystalline alumina, or spinel, as long as it solves the technical problem of the present invention.

As the material of the piezoelectric layer 3, lithium tantalate (LiTaO₃) or lithium niobate (LiNbO₃) may be used. However, the material of the piezoelectric layer 3 is not limited to these and may include other materials.

The IDT electrode 4 may be formed using, for example, Al, Au, Cu, Ni, Pt, Ti, Cr, Ag, or alloys thereof; however, other metals or alloys may also be used. The IDT electrode 4 may also be configured by laminating these metals or alloys.

The intermediate layer 6 is provided at least to improve the bonding strength between the support substrate 2 and the piezoelectric layer 3 or to increase the propagation speed of elastic waves.

When the intermediate layer 6 is intended to enhance the bonding strength between the support substrate 2 and the piezoelectric layer 3, it may be made of silicon dioxide (SiO₂) or similar materials.

When the intermediate layer 6 is intended to increase the propagation speed of elastic waves, it may be made of aluminum nitride (AlN) or boron aluminum nitride (BₓAl₁₋ₓN) or similar materials. In this embodiment, the intermediate layer 6 may also be omitted.

In manufacturing the elastic wave resonator 1, as the piezoelectric layer 3, lithium tantalate (LiTaO₃) with 36° Y-cut X propagation or 42° Y-cut X propagation may be used.

As shown in FIG. 2, in a top view of the IDT electrode 4, the first bus bar 11a and the second bus bar 11b have multiple stepped portions on the side facing each other, and these stepped portions are parallel to the propagation direction of surface acoustic waves (X-direction in FIG. 2). The first bus bar 11a includes a first stepped portion 21a, a second stepped portion 22a, and a third stepped portion 23a. The second bus bar 11b includes a first stepped portion 21b, a second stepped portion 22b, and a third stepped portion 23b. These stepped portions, together with the step portions described below, form a stepped structure on the opposing sides of the bus bars 11a and 11b.

In the IDT electrode 4, three flat regions, namely a first flat region 51, a second flat region 52, and a third flat region 53, are arranged in the X-direction indicated by the arrow in FIG. 2. The first flat region 51, the second flat region 52, and the third flat region 53 correspond to the regions where the first stepped portion 21a, the second stepped portion 22a, and the third stepped portion 23a are located, respectively.

The first stepped portion 21a is positioned at the height defined by a virtual line L1a. (In this embodiment, “height” refers to the dimension in the extending direction of the electrode fingers, which is parallel to the direction from the first bus bar to the second bus bar.) The second stepped portion 22a is positioned at the height defined by a virtual line L2a, and the third stepped portion 23a is positioned at the height defined by a virtual line L3a. Similarly, the first stepped portion 21b is positioned at the height defined by a virtual line L1b, the second stepped portion 22b at the height defined by a virtual line L2b, and the third stepped portion 23b at the height defined by a virtual line L3b. Furthermore, the distances between corresponding stepped portions are all substantially equal, specifically, the distances between virtual lines L1a and L1b, L2a and L2b, and L3a and L3b are all equal.

The IDT electrode 4 further includes step portions 31a, 31b, 32a, and 32b. The step portion 31a is positioned between the first stepped portion 21a and the adjacent second stepped portion 22a, forming a step along the direction from the first stepped portion 21a to the second stepped portion 22a, in the direction from the first bus bar 11a toward the second bus bar 11b. The step portion 31b is positioned between the stepped portion 21b and the adjacent stepped portion 22b, forming a step along the direction from stepped portion 21b to stepped portion 22b, in the direction from the first bus bar 11a toward the second bus bar 11b. The step portion 32a is positioned between the second stepped portion 22a and the adjacent third stepped portion 23a, forming a step along the direction from the second stepped portion 22a to the third stepped portion 23a, in the direction from the first bus bar 11a toward the second bus bar 11b.

The step portion 32b is positioned between the stepped portion 22b and the adjacent stepped portion 23b, forming a step along the direction from stepped portion 22b to stepped portion 23b, in the direction from the first bus bar 11a toward the second bus bar 11b.

All of these step portions 31a, 31b, 32a, and 32b are formed along the direction from the first bus bar 11a to the second bus bar 11b, which is perpendicular to the propagation direction X of the surface acoustic waves. The stepped portions and step portions are alternately arranged, forming an overall stepped structure.

In describing the embodiments of the present invention, the term “step” refers to the distance between adjacent stepped portions in the extending direction of the electrode fingers (i.e., from the first bus bar to the second bus bar).

In the IDT electrode 4, the electrode fingers 12a on the first bus bar 11a side and the electrode fingers 12b on the second bus bar 11b side have the same length. The dummy electrodes 15a and 15b also have the same length. The distances between the gaps 17a and 17b and their respective nearest stepped portions are uniform. The aperture length of the IDT electrode 4 (the length of the crossover region in the extending direction of the electrode fingers) is the same across all regions of the first flat region 51, second flat region 52, and third flat region 53.

In the elastic wave device with the above-described structure, the suppression effect on transverse modes is explained. To verify the effect of the elastic wave device 1 of the present embodiment, multiple elastic wave devices with different step structures were fabricated, including comparative examples and SAW resonators in the embodiments, and their characteristics were measured.

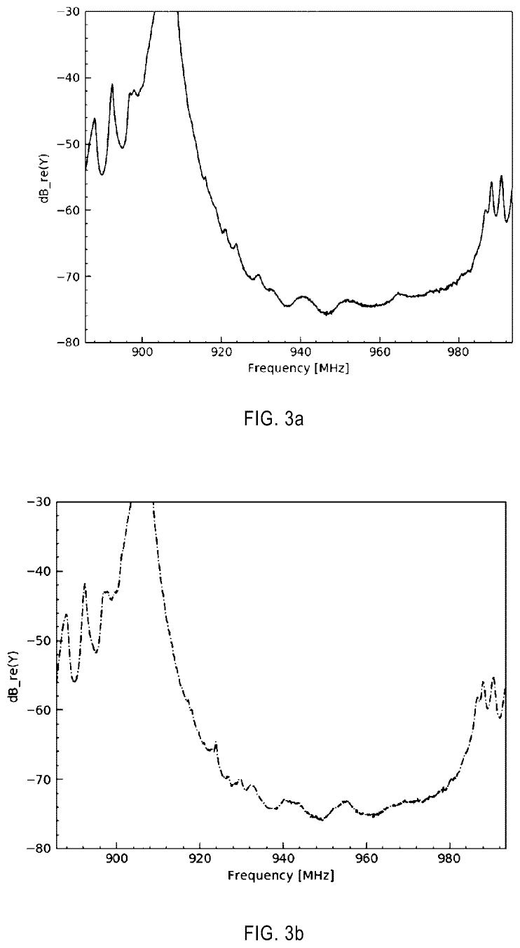

FIG. 3(a) illustrates the relationship between frequency and the real part of admittance, Re(Y), for the elastic wave device of Embodiment 1, where the step heights of step portions 31a, 31b, 32a, and 32b are set to 1.0λ.

FIG. 3(b) illustrates the relationship between frequency and Re(Y) for the elastic wave device of Embodiment 2, where the step height is 0.5λ.

FIG. 3(c) illustrates the relationship between frequency and Re(Y) for the comparative example, which does not include step portions.

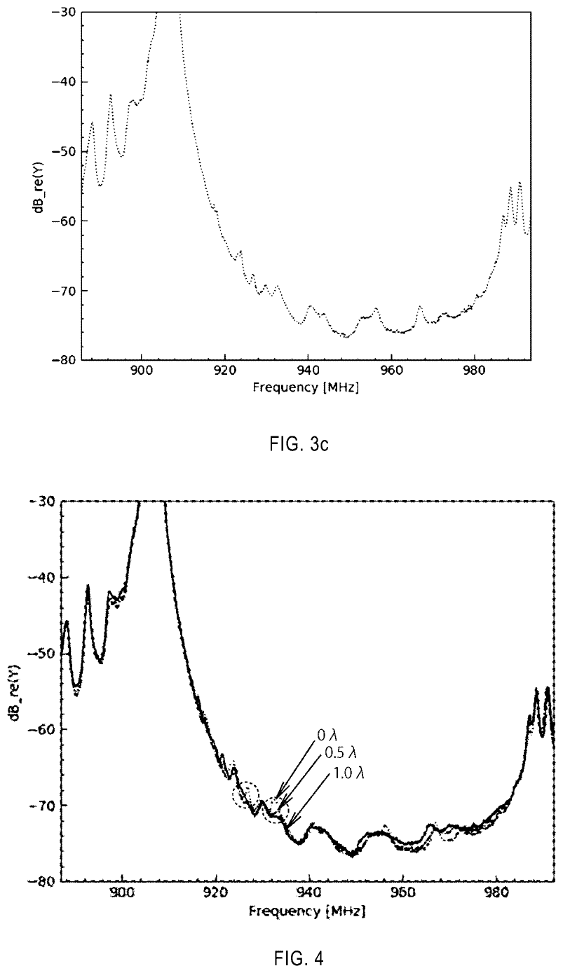

FIG. 4 superimposes the frequency characteristics of these three examples.

In these graphs, the horizontal axis represents frequency (unit: MHz), while the vertical axis represents the real part of admittance Re(Y) (unit: dB). Furthermore, to enhance the visibility of the portion where Re(Y) is below −30 dB, values exceeding −30 dB are omitted.

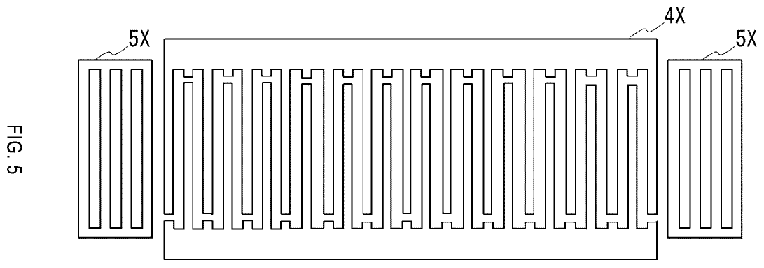

FIG. 5 shows a plan view of the IDT electrode 4X and reflector 5X for elastic wave device of the comparative example, which does not include step portions in the IDT electrode 4X.

The common conditions for the comparative example, Embodiment 1, and Embodiment 2 are as follows:
Wavelength (A): 4.1 μm

Piezoelectric substrate 3:
Material: 42° rotated Y-cut X-propagation lithium tantalate substrate
Thickness: 0.27λ

Intermediate layer 6:
Material: SiO₂
Thickness: 0.61

Support substrate 2:
Material: Spinel
Thickness: 97.6λ

IDT electrode fingers:
IDT film structure: Composed of a bottom Ti layer (130 nm), a middle AlCu layer (268 nm), and a top Ti layer (15 nm)
Pitch: 0.5λ
Duty ratio: 46%
Number of electrode finger pairs: 114
Aperture length: 17.5λ
Dummy electrode length: 0.5λ
Gap: 0.45 μm
Number of reflectors: 10

As shown in FIG. 4, particularly from the circled portions, it can be observed that compared to the comparative example without steps (represented by the dashed line and labeled as “0λ” in FIG. 4 for convenience), the peak value of the real part of admittance in Embodiment 2 (represented by the dashed-dotted line) is smaller, indicating that the transverse mode is suppressed. Furthermore, compared to Embodiment 2 with a step height of 0.5λ, Embodiment 1 (represented by the solid line and having a step height of 1.0λ) exhibits an even smaller peak value of Re(Y), demonstrating further suppression of the transverse mode.

Accordingly, because the elastic wave device of the first embodiment is provided with step portions 31a, 31b, 32a, and 32b, transverse mode suppression can be effectively achieved.

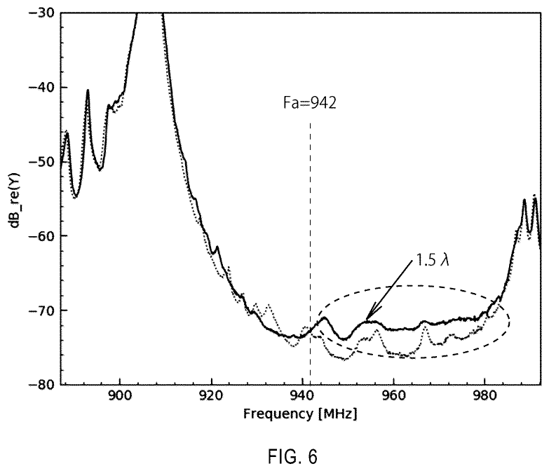

As shown in FIG. 6, the solid line represents Embodiment 3, in which the step height of step portions 31a, 31b, 32a, and 32b is set to 1.5). This figure illustrates the real part of admittance for the elastic wave device at different frequencies. The dashed line represents the real part of admittance for the elastic wave device without step portions at different frequencies.

From FIG. 6, it can be observed that, particularly in the frequency range from the anti-resonance frequency Fa (approximately 942 MHz) to 980 MHz, the real part of admittance increases. Since an increase in Re(Y) within this frequency range implies insufficient suppression of surface acoustic waves when used as a filter, this phenomenon is undesirable. Additionally, as the step height increases, Re(Y) in the 942 MHz to 980 MHz range exhibits an upward trend. Therefore, the step height should preferably be set to less than 1.5λ. Furthermore, in the IDT electrode 4, an excessively large total step height leads to increased energy loss, which is also undesirable.

Specifically, the total step height of step portions 31a and 32a (i.e., the distance from virtual line L1a to virtual line L3a) should preferably be set to less than 2.0λ. Similarly, the total step height of step portions 31b and 32b (i.e., the distance from virtual line L1b to virtual line L3b) should preferably be set to less than 2.0λ.

### Second Embodiment

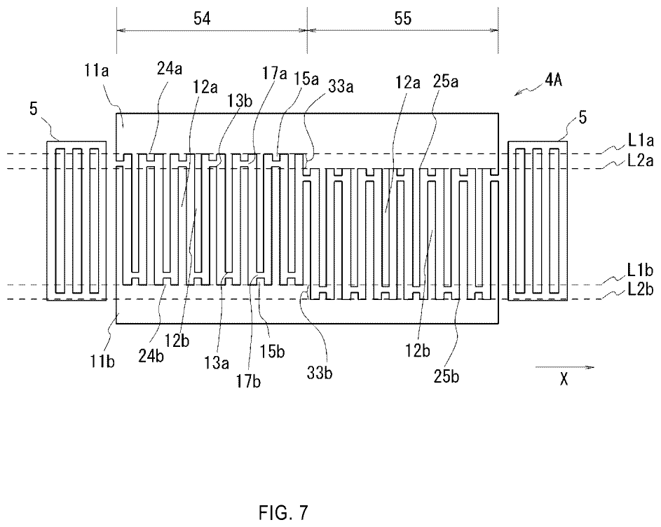

FIG. 7 shows a top view of the IDT electrode 4A of the elastic wave device according to the second embodiment. In the following description, elements having the same names and functions as those in the previous embodiment retain the same reference numerals, and redundant descriptions are omitted.

In the second embodiment, the IDT electrode 4A consists of two sections, a first flat region 54 and a second flat region 55.

In the first bus bar 11a, a step portion 33a is formed between the first step section 24a and the adjacent second step section 25a.

In the second bus bar 11b, a step portion 33b is formed between the first step section 24b and the adjacent second step section 25b.

The first step section 24a is positioned defined by a virtual line La1, while the second step section 25a is positioned defined by a virtual line La2. The first step section 24b is positioned defined by a virtual line Lb1, while the second step section 25b is positioned defined by a virtual line Lb2.

As described above, in the elastic wave device adopting the two-section structure IDT electrode 4A, transverse mode suppression can be achieved. To verify the effect of the elastic wave device 1 of this embodiment, multiple elastic wave devices (including SAW resonators in both comparative examples and the Second Embodiment) with different step heights were fabricated, and measured.

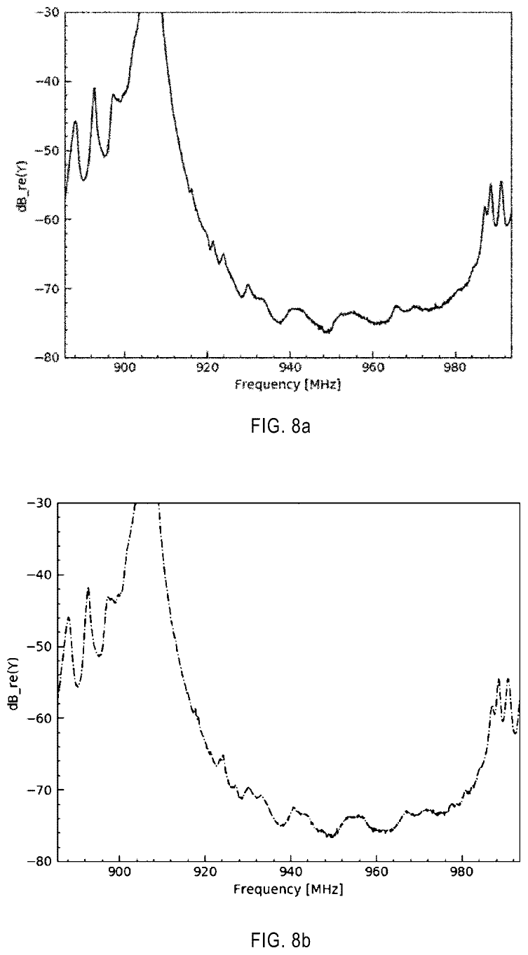

FIG. 8a illustrates the relationship between frequency and Re(Y) for Embodiment 4, where the step heights of step portions 33a and 33b in the IDT electrode 4A shown in FIG. 7 are set to 1.0λ.

FIG. 8b illustrates the relationship between frequency and Re(Y) for Embodiment 5, where the step heights of step portions 33a and 33b in the IDT electrode 4A shown in FIG. 7 are set to 0.5λ.

FIG. 8c illustrates the relationship between frequency and Re(Y) for the comparative example, where the elastic wave device employs an IDT electrode without steps (see FIG. 5).

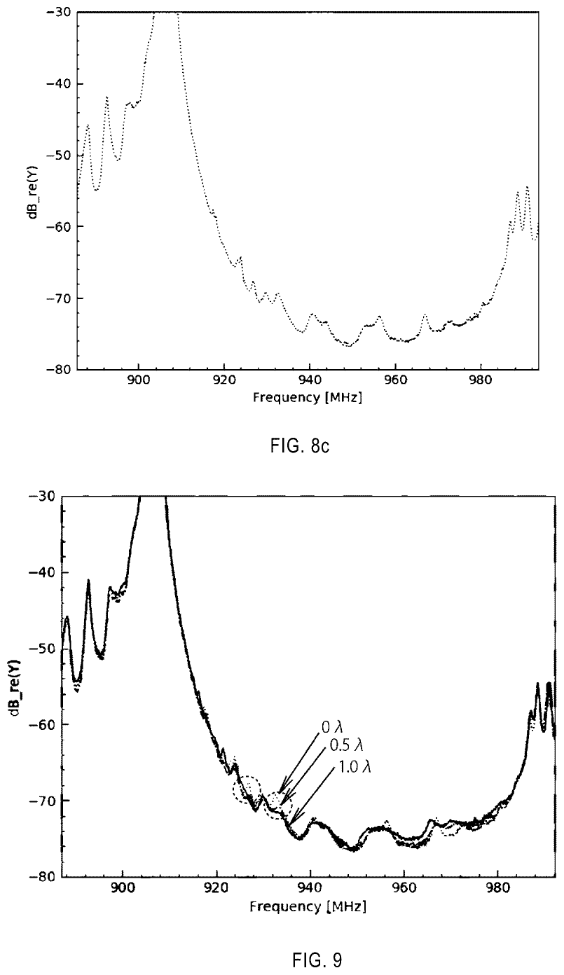

FIG. 9 superimposes the frequency characteristics of these three examples. The fabrication and measurement conditions are the same as those in Embodiments 1, 2, and 3.

As shown in FIG. 9, particularly in the portions marked by dashed-line circles, compared to the comparative example without steps, Embodiment 5 with a step height of 0.5λ exhibits a smaller peak value of Re(Y), indicating suppression of the transverse mode. Furthermore, compared to Embodiment 5 with a step height of 0.5λ, Embodiment 4 with a step height of 1.0λ exhibits an even smaller peak value of Re(Y), demonstrating further suppression of the transverse mode.

Therefore, because the IDT electrode 4A of the elastic wave resonator in the second embodiment is provided with step portions 31a, 31b, 32a, and 32b, transverse mode suppression can be effectively achieved. This confirms that transverse mode suppression can be achieved as long as the IDT electrode includes step structures.

### Third Embodiment

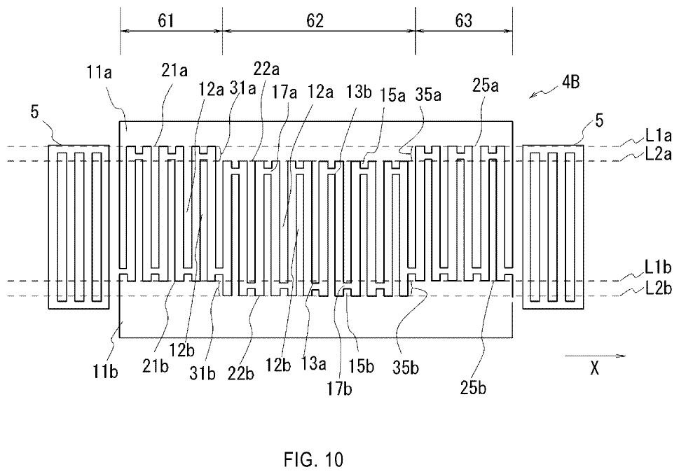

FIG. 10 shows a top view of the IDT electrode 4A of the elastic wave device according to the third embodiment. As shown in FIG. 10, the IDT electrode adopts a three-section structure. Specifically, step portions 31a and 31b are formed downward (i.e., toward the second bus bar 11b) from the first flat region 61 to the second flat region 62, while step portions 32a and 32b are formed upward (i.e., toward the first bus bar 11a) from the second flat region 62 to the third flat region 63.

Since step portions 31a, 31b, 35a, and 35b are provided in the elastic wave device, transverse mode suppression can be effectively achieved.

### Fourth Embodiment

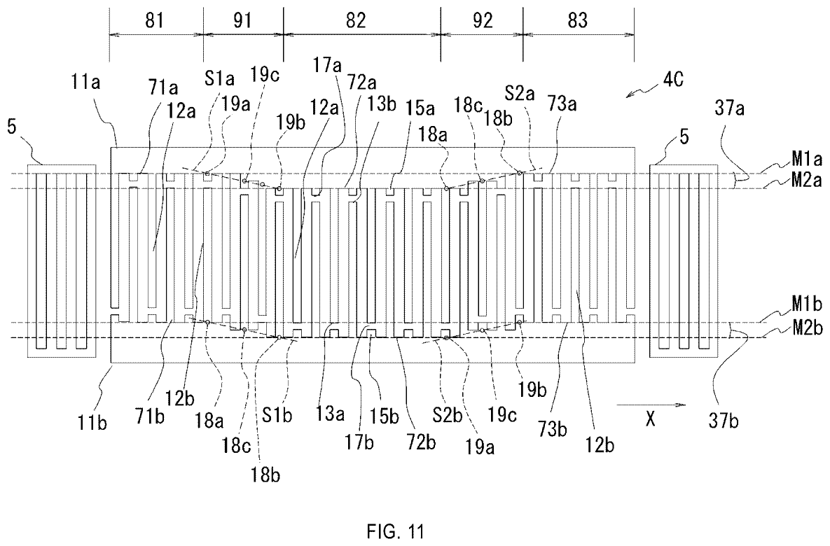

FIG. 11 shows a top view of the IDT electrode 4C of the elastic wave device according to the fourth embodiment. As illustrated in FIG. 11, the IDT electrode 4C includes a first flat region 81, a second flat region 82, and a third flat region 83, along with ramp regions 91 and 92, which serve as regions with inclined step portions.

In the IDT electrode 4C, as shown in FIG. 11, a transition gradually descends from the first flat region 81 to the second flat region 82 through the ramp region 91, in the downward direction (i.e., from the first bus bar 11a toward the second bus bar 11b). Conversely, from the second flat region 82 to the third flat region 83, a transition gradually ascends through the ramp region 92, in the upward direction (i.e., from the second bus bar 11b toward the first bus bar 11a).

The ramp regions 91 and 92 refer to regions where the bases of electrode fingers 18a, 18b, 18c or the bases of dummy electrodes 19a, 19b, 19c are arranged along inclined virtual lines S1a, S1b, S2a, and S2b. In these ramp regions, because the bases of electrode fingers 18a, 18b, 18c or the bases of dummy electrodes 19a, 19b, 19c are arranged adjacently along the inclined virtual lines S1a, S1b, S2a, and S2b, an inclined step portion (ramp) is formed. This ramp-like structure is created by the arrangement of these bases.

On the virtual line S1a of ramp region 91, the bases 19a, 19b, and 19c of the dummy electrode 15b are provided. Along the extension direction of the electrode fingers, base 19a is positioned at step portion 71a (virtual line M1a), base 19b is positioned at step portion 72a (virtual line M2a), and base 19c is positioned between virtual line M1a and virtual line M2a.

On the virtual line S1b of ramp region 91, the bases 18a, 18b, and 18c of the electrode finger 12b are provided. Along the extension direction of the electrode fingers, base 18a is positioned at step portion 71b (virtual line M1b), base 18b is positioned at step portion 72b (virtual line M2b), and base 18c is positioned between virtual line M1b and virtual line M2b.

In ramp region 91, because at least one base 18c or 19c is provided between step portions 37a or 37b, the adjacent bases are arranged in an inclined manner, thereby forming the ramp structure and constituting the ramp region. In this embodiment, only one base is arranged between step portions 37a or 37b on each virtual line (S1a or S1b), but multiple bases may also be arranged.

On the virtual line S2a of ramp region 92, the bases 18a, 18b, and 18c of electrode fingers 12a are provided. Along the extension direction of the electrode fingers, base 18a is positioned at step portion 72a (virtual line M2a), base 18b is positioned at step portion 73a (virtual line M1a), and base 18c is positioned between virtual line M1a and virtual line M2a.

On the virtual line S2b of ramp region 92, the bases 19a, 19b, and 19c of the dummy electrodes 15b are provided. Along the extension direction of the electrode fingers, base 19a is positioned at step portion 72b (virtual line M2b), base 19b is positioned at step portion 73b (virtual line M1b), and base 19c is positioned between virtual line M1b and virtual line M2b.

In the ramp region 92, because at least one base 18c or 19c is provided between step portions 37a or 37b, the adjacent bases are arranged in an inclined manner, thereby forming the ramp structure and constituting the ramp region. In the present embodiment, only one base is arranged between step portions 37a or 37b on each virtual line (S2a or S2b), but multiple bases may also be arranged.

On the first bus bar 11a, a flat portion extending parallel in the X direction is provided, including step portions 71a, 72a, and 73a. Step portions 71a and 73a are positioned on virtual line M1a, while step portion 72a is positioned on virtual line M2a. The spacing between virtual lines M1a and M2a corresponds to the height of step portion 37a (i.e., the vertical spacing shown in FIG. 11).

On the second bus bar 11b, step portions 71b, 72b, and 73b are provided. Step portions 71b and 73b are positioned on virtual line M1b, while step portion 72b is positioned on virtual line M2b. The spacing between virtual lines M1a and M2a corresponds to the height of step portion 37b (i.e., the vertical spacing shown in FIG. 11).

As described above, in the IDT electrode 4C, since step portions 37a and 37b are provided along the direction from the first bus bar to the second bus bar (perpendicular to the direction propagation of the surface acoustic wave) via ramp regions 91 and 92 between adjacent step portions, transverse mode suppression of the elastic wave resonator can be effectively achieved.

Additionally, this embodiment employs a ramped step structure where bases 18b and 19c are arranged between step portions 37a and 37b. Compared to the non-ramped step structures used in the first to third embodiments, this structure can more effectively improve the Q factor. Furthermore, in this embodiment, the step heights of step portions 37a and 37b in ramp regions 91 and 92 are the same, but they may also be set to different heights.

Similar to the first embodiment, the width of the step portions in the extension direction of the electrode fingers is preferably less than 1.5λ, and the total step height of step portions 37a and 38a (i.e., the distance from virtual line M1a to virtual line M3a), as well as the total step height of step portions 37b and 38b (i.e., the distance from virtual line M1b to virtual line M3b), are preferably less than 2.0λ.

The width of ramp regions 91 and 92 in the X direction is described as follows. The widths of ramp regions 91 and 92 in the X direction are shorter than those of step portions 71b, 72b, and 73b. By setting the widths of ramp regions 91 and 92 shorter than those of the flat step portions 71b, 72b, and 73b, peak values in the high-frequency range (such as the peak around 988 MHz in FIG. 9, which may also appear in the frequency-admittance relationship curve of the present embodiment) may shift toward the resonance frequency side (e.g., around 910 MHz in FIG. 9, which is the lower frequency side), thereby preventing such phenomena and maintaining favorable frequency characteristics.

In the IDT electrode 4C, the lengths of electrode finger 12a connected to the first bus bar 11a and electrode finger 12b connected to the second bus bar 11b side are the same. The lengths of dummy electrodes 15a and 15b are also substantially identical. The gaps 17a and 17b maintain nearly equal distances from the electrode finger bases 18 within their nearest step portions or ramp regions. The aperture length of the IDT electrode 4 (the length of the overlapping region in the electrode finger direction) is substantially uniform across all regions, including flat regions 81, 82, and 83, as well as ramp regions 91 and 92.

Furthermore, within ramp regions 91 and 92, gaps 17a and 17b are also arranged in a continuously sloping manner, forming a ramp-like structure.

### Fifth Embodiment

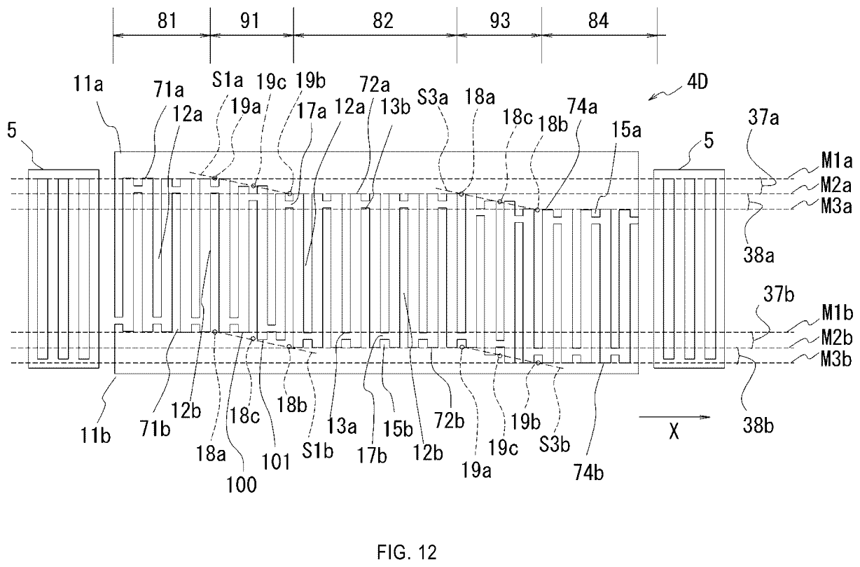

FIG. 12 shows a top view of the IDT electrode 4D of the elastic wave resonator according to the fifth embodiment. As illustrated in FIG. 12, the IDT electrode 4D includes a first flat region 81, a second flat region 82, and a third flat region 84, along with ramp regions 91 and 93, which serve as regions with inclined step portions. In the IDT electrode 4D, a transition gradually descends from the first flat region 81 to the second flat region 82 through the ramp region 91 in the downward direction as shown in FIG. 12 (i.e., from the first bus bar 11a toward the second bus bar 11b). Further, from the second flat region 82 to the third flat region 84, a transition continues to descend through the ramp region 93.

The ramp regions 91 and 93 refer to regions where the bases of electrode fingers 12a, 12b, or the bases of dummy electrodes 19a, 19b, 19c are arranged along inclined virtual lines S1a, S1b, S3a, and S3b. These virtual lines are inclined relative to both the extension direction of the electrode fingers and the propagation direction of the surface acoustic wave.

In ramp region 91, the bases 19a, 19b, and 19c of the dummy electrodes 15a are arranged in a sloped configuration along the inclined virtual line S1a. In the extension direction of the electrode fingers, base 19a is positioned at step portion 71a (virtual line M1a), base 19b is positioned at step portion 72a (virtual line M2a), and base 19c is positioned between virtual line M1a and virtual line M2a.

Similarly, in ramp region 91, the bases 18a, 18b, and 18c of electrode fingers 12b are arranged in a sloped configuration along the inclined virtual line S1b. In the extension direction of the electrode fingers, base 18a is positioned at step portion 71b (virtual line M1b), base 18b is positioned at step portion 72b (virtual line M2b), and base 18c is positioned between virtual line M1b and virtual line M2b.

In ramp region 93, the bases 18a, 18b, and 18c of electrode fingers 12a are arranged in a sloped configuration along the inclined virtual line S3a. In the extension direction of the electrode fingers, base 18a is positioned at step portion 72a (virtual line M2a), base 18b is positioned at step portion 74a (virtual line M3a), and base 18c is positioned between virtual line M2a and virtual line M3a.

Similarly, in ramp region 93, the bases 19a, 19b, and 19c of the dummy electrodes 15b are arranged in a sloped configuration along the inclined virtual line S3b. In the extension direction of the electrode fingers, base 19a is positioned at step portion 72b (virtual line M2b), base 19b is positioned at step portion 74b (virtual line M3b), and base 19c is positioned between virtual line M2b and virtual line M3b.

On the first bus bar 11a, step portions 71a, 72a, and 74a are provided. Step portion 71a is positioned at virtual line M1a, step portion 72a is positioned at virtual line M2a, and step portion 74a is positioned at virtual line M3a. The spacing between virtual lines M1a and M2a corresponds to the height of step portion 37a (i.e., the vertical spacing shown in FIG. 12), while the spacing between virtual lines M2a and M3a corresponds to the height of step portion 38a.

On the second bus bar 11b, step portions 71b, 72b, and 74b are provided. Step portion 71b is positioned at virtual line M1b, step portion 72b is positioned at virtual line M2b, and step portion 74b is positioned at virtual line M3b.

The spacing between virtual lines M1b and M2b corresponds to the height of step portion 37b (i.e., the vertical spacing shown in FIG. 12), while the spacing between virtual lines M2b and M3b corresponds to the height of step portion 38b.

By forming step portions 37a, 37b, 38a, and 38b in the extension direction of the electrode fingers (i.e., the direction perpendicular to the propagation direction of the surface acoustic wave) through ramp regions 91 and 93, the IDT electrode 4D can effectively suppress transverse modes in the elastic wave device.

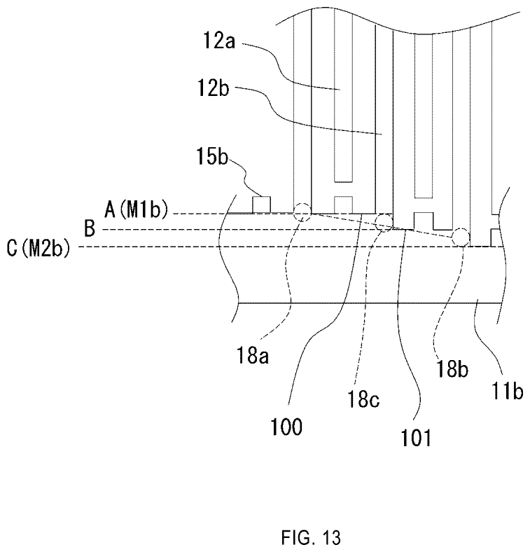

FIG. 13 presents a magnified view of a portion of the IDT electrode 4D. Regarding the position of electrode finger base 18c, as shown in FIG. 13, if there is a deviation in the lateral position of the electrode finger root (i.e., the intersection of the edge portions 100 and 101 on the bus bar 11b side in the crossover region with the contour of electrode finger 12b), then base 18c should be positioned between these locations (i.e., near the region indicated by the dashed box in FIG. 13). The same approach should be applied to other electrode finger bases and dummy electrode bases if deviations exist in their lateral root positions.

### Sixth Embodiment

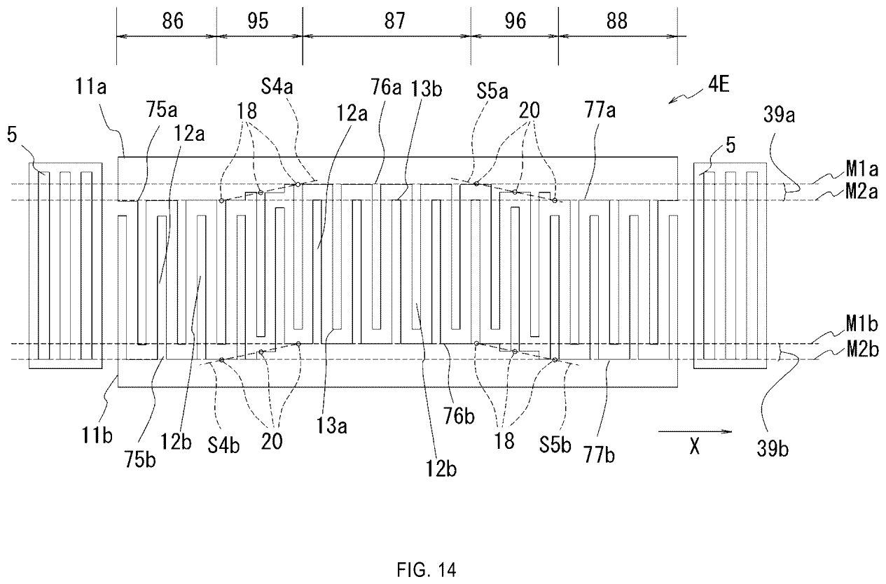

FIG. 14 shows a top view of the IDT electrode 4E of the elastic wave device according to the sixth embodiment. As illustrated in FIG. 14, the IDT electrode 4E in this embodiment does not include dummy electrodes. In the IDT electrode 4E, at locations corresponding to the dummy electrode bases in the previous embodiments, the side edge portions 20 of the bus bars 11a and 11b, which are close to the electrode fingers are arranged in a sloped-like configuration along inclined virtual lines S4b and S5a. Additionally, the bases 18 of the electrode fingers are arranged in a sloped configuration along virtual lines S4a and S5b.

The IDT electrode 4E includes a first flat region 86, a second flat region 87, and a third flat region 88, along with ramp regions 95 and 96, which serve as regions with inclined step portions.

In the IDT electrode 4E, a transition rises from the first flat region 86 to the second flat region 87 through the ramp region 95 in the upward direction as shown in FIG. 14 (i.e., from the second bus bar 11b toward the first bus bar 11a). Further, from the second flat region 87 to the third flat region 88, a transition descends through the ramp region 96.

As described above, by forming step portions 39a and 39b in the extension direction of the electrode fingers (i.e., the direction perpendicular to the propagation direction X of the surface acoustic wave) through ramp regions 95 and 96, the IDT electrode 4E can effectively suppress transverse modes in the elastic wave device.

In the above embodiments, the relative positional relationship between the first bus bar 11a and the second bus bar 11b may also be reversed. Furthermore, the present invention is also applicable to elastic wave devices that do not include dummy electrodes 15a and 15b, as well as those without reflectors 5.

It should be noted that the illustrations used in the above descriptions are schematic, and dimensions, proportions, and other aspects in the figures may not necessarily correspond exactly to the actual product.

The present invention has been described above. However, as an elastic wave device, the specific embodiments of the invention are not limited to the above examples, and various modifications and additional changes can be made without departing from the core technical concept of the invention.

Although multiple aspects of some embodiments have been described, it should be understood that those skilled in the art may readily conceive various modifications, improvements, and enhancements. These modifications, improvements, and enhancements are intended to be part of the invention and fall within the scope of this disclosure.

The specific implementations provided are for illustrative purposes only and are not intended to be limiting.

The expressions and terms used in this disclosure are for explanatory purposes and should not be considered restrictive. The terms “comprising,” “including,” “having,” and “containing,” and their variations, are intended to cover the listed items as well as their equivalents and additional elements.

The term “or” is intended to be understood as covering any one, more than one, or all of the listed terms.

References to directions such as front, back, left, right, top, bottom, up, down, horizontal, vertical, inner, and outer are for descriptive convenience. These references do not restrict the components of the present invention to any particular positional or spatial orientation. Accordingly, the above descriptions and illustrations are merely exemplary.

What is claimed is:

1. An elastic wave device, comprises a piezoelectric layer and an IDT electrode formed on the piezoelectric layer, wherein the IDT electrode includes a first bus bar and a second bus bar opposed to the first bus bar;
in a top view, the first bus bar and the second bus bar each have multiple stepped portions on their facing sides, with these stepped portions aligned parallel to a propagation direction of the surface acoustic wave, and a distance between the corresponding stepped portions of the first bus bar and the second bus bar is uniform; wherein adjacent of the stepped portions are arranged at different positions in a direction from the first bus bar to the second bus bar, a step portion is provided between them.

2. The elastic wave device according to claim 1, wherein a width of the step portion perpendicular to the propagation direction of the surface acoustic wave is less than 1.5λ, wherein λ is a wavelength of the acoustic wave.

3. The elastic wave device according to claim 1, wherein the first bus bar and the second bus bar each include:
a first stepped portion, a second stepped provided portion adjacent to the first stepped portion, and a third stepped portion provided adjacent to the second stepped portion, and
a first step portion provided between the first stepped portion and the second stepped portion, which forming a step in a direction from the first stepped portion toward the second stepped portion and extending from the first bus bar toward the second bus bar.
a second step portion provided between the second stepped portion and the third stepped portion, which forming a step in a direction from the second stepped portion toward the third stepped portion and extending from the second bus bar toward the first bus bar.

4. The elastic wave device according to claim 1, wherein the first bus bar and the second bus bar each include:
a first stepped portion,
a second stepped portion provided adjacent to the first stepped portion,
a third stepped portion provided adjacent to the second stepped portion,
a first step portion provided between the first stepped portion and the second stepped portion, and
a second step portion provided between the second stepped portion and the third stepped portion;
in a sequence of the first stepped portion, the second stepped portion, and the third stepped portion changes, the step portions are formed in a same direction which is from the second bus bar toward the first bus bar or from the first bus bar toward the second bus bar.

5. The elastic wave device according to claim 1, wherein the first bus bar and the second bus bar each include:
a first stepped portion,
a second stepped portion provided adjacent to the first stepped portion,
a third stepped portion provided adjacent to the second stepped portion,
a first step portion provided between the first stepped portion and the second stepped portion, and
a second step portion provided between the second stepped portion and the third stepped portion;
wherein a total height of the step portions in a direction from the first bus bar to the second bus bar is less than 2.0λ, wherein λ is a wavelength of the elastic wave.

6. The elastic wave device according to claim 1, wherein the step portion is formed in a direction perpendicular to a propagation direction of the surface acoustic wave.

7. The elastic wave device according to claim 1, wherein the step portion has multiple end portions arranged along an inclined virtual line, which is inclined relative to the propagation direction of the elastic wave.

8. The elastic wave device according to claim 1, wherein in a top view of the IDT electrode, both the first bus bar and the second bus bar include a first flat region, a second flat region, a third flat region, and ramp regions provided between adjacent flat regions.

9. The elastic wave device according to claim 8, wherein the IDT electrode further includes multiple first electrode fingers extending from the first bus bar toward the second bus bar, multiple second electrode fingers extending from the second bus bar toward the first bus bar, and dummy electrodes facing the first electrode fingers and the second electrode fingers, respectively, with gaps formed between the end portions of the electrode fingers and the dummy electrodes, and the ramp region is defined by base portions of the electrode fingers or the dummy electrodes are arranged along an inclined virtual line.

10. The elastic wave device according to claim 9, wherein the ramp region serves as the step portion between adjacent stepped portions, and at least one of the base portions of the electrode fingers or the base portions of the dummy electrodes is provided in the step portion, such that the base portions of adjacent electrode fingers or adjacent dummy electrodes are arranged in an inclined manner, thereby forming a ramp structure and constituting the ramp region.

11. The elastic wave device according to claim 9, wherein in a closest stepped portion or ramp region, a distance between each gap and the base portions of the electrode fingers is substantially uniform.

12. The elastic wave device according to claim 9, wherein the first electrode fingers and the second electrode fingers have substantially the same length.

13. The elastic wave device according to claim 8, wherein in the IDT electrode, a transition from the first flat region to the second flat region occurs through the first ramp region, gradually descending in the direction from the first bus bar toward the second bus bar, a transition from the second flat region to the third flat region occurs through the second ramp region, gradually ascending in the direction from the second bus bar toward the first bus bar.

14. The elastic wave device according to claim 8, wherein a width of the step portion in the extending direction of the electrode fingers is less than 1.5λ, wherein λ is a wavelength of the elastic wave.

15. The elastic wave device according to claim 8, wherein in the propagation direction of the elastic wave, the ramp region has a width that is respectively smaller than the width of the first flat region, the second flat region, and the third flat region.

16. The elastic wave device according to claim 8, wherein in the IDT electrode, a transition from the first flat region to the second flat region occurs through the first ramp region, gradually descending along the direction from the first bus bar toward the second bus bar, and a transition from the second flat region to the third flat region occurs through the second ramp region, further descending along the direction from the first bus bar toward the second bus bar.

17. The elastic wave device according to claim 8, wherein in the IDT electrode, a transition from the first flat region to the second flat region occurs through the first ramp region, gradually ascending along the direction from the second bus bar toward the first bus bar, and a transition from the second flat region to the third flat region occurs through the second ramp region, gradually descending along the direction from the first bus bar toward the second bus bar.

18. The elastic wave device according to claim 8, wherein the IDT electrode further includes multiple first electrode fingers extending from the first bus bar toward the second bus bar and multiple second electrode fingers extending from the second bus bar toward the first bus bar, wherein end portions of the first bus bar and the second bus bar, near the electrode fingers, are arranged in a ramp shape along an inclined virtual line which is inclined relative to the propagation direction of the elastic wave.

19. The elastic wave device according to claim 18, wherein base portions of the electrode fingers are arranged in a ramp shape along the virtual line.

20. The elastic wave device according to claim 1, wherein the IDT electrode further includes multiple first electrode fingers extending from the first bus bar toward the second bus bar and multiple second electrode fingers extending from the second bus bar toward the first bus bar, wherein the first electrode fingers and the second electrode fingers have crossover regions, and in an extending direction of the electrode fingers, the crossover regions have the same length at each stepped portion and step portion.
